(19) United States
(12) Patent Application Publication
(10) Pub. No.: US 2014/0080313 A1
(43) Pub. Date: Mar. 20, 2014

(54) ETCHING COMPOSITION AND METHOD FOR ETCHING A SEMICONDUCTOR WAFER

(71) Applicant: INDUSTRIAL TECHNOLOGY RESEARCH INSTITUTE, Chutung (TW)

(72) Inventors: Sheng-Min YU, Chutung (TW); Wen-Ching SUN, Chutung (TW); Tai-Jui WANG, Chutung (TW); Yi-Fan CHEN, Chutung (TW); Chia-Liang SUN, Chutung (TW); Hao-Hsiang CHIANG, Chutung (TW); Pin-Guan LIAO, Chutung (TW); Chi-Fan CHIANG, Chutung (TW); Tzer-Shen LIN, Chutung (TW)

(73) Assignee: INDUSTRIAL TECHNOLOGY RESEARCH INSTITUTE, Chutung (TW)

(21) Appl. No.: 13/725,419

(22) Filed: Dec. 21, 2012

(30) Foreign Application Priority Data
Sep. 20, 2012 (TW) 101134424

(51) Int. Cl. H01L 21/306

(52) U.S. Cl. CPC H01L 21/30604
USPC 438/749; 252/79.4

(57) ABSTRACT

An etching composition for a semiconductor wafer is provided, including 0.5-50 wt % base, 10-80 wt % alcohol, 0.01-15 wt % additive and water. A method for etching a semiconductor wafer is also provided. When the etching composition is applied to the entire surface or a partial surface of the semiconductor wafer at 60-200° C., the etching composition reacts on the semiconductor wafer to form a foam that etches the semiconductor wafer and includes a solid, a liquid and a gas. At the same time, the additive forms an oxide mask on the surface of the semiconductor wafer. Therefore, an excellent texture structure is formed on the surface of the semiconductor wafer, and a single surface of the semiconductor wafer is etched.

### CROSS-REFERENCE TO RELATED APPLICATION

The present application is based on, and claims priority from, Taiwan (International) Application Serial Number 101134424, filed on Sep. 20, 2012, and the disclosure of which is hereby incorporated by reference herein.

### BACKGROUND

1. Technical Field

The technical field relates to etching compositions and methods for etching a semiconductor wafer and, more particularly, to an etching composition that forms a texture structure on a surface of a semiconductor wafer and a method for etching the same.

2. Description of Related Art

In order to solve the problems of environment pollution and power shortage, solar industry develops rapidly. A solar cell converts light into electricity.

In order to increase the conversion efficiency of a solar cell, a chip installed in the solar cell has to be controlled in an efficient manner. For example, the roughness of a front surface and the smoothness of a rear surface may affect the efficiency of the chip. In a passivated emitter and rear cell (PERC) and an interdigitated back contact (IBC) solar cell, a silicon chip, if having a texture structure formed on the front surface and a smooth rear surface, may increase the conversion efficiency of the cells.

In a conventional process of fabricating a solar cell, the rough front surface and the smooth rear surface of a chip are obtained by immersing the chip in an etching solution. The chip is first immersed in a roughness etching solution to form a roughness structure on both surfaces of the chip. Then, a protection cover is formed on one surface of the chip, and the chip is immersed in a smoothness etching solution. As a result, the chip has one surface roughed and the other surface smoothed. However, in the conventional process the chip is easily damaged or has an additional thickness loss. Besides, the forming and removal of the protection cover increase the cost of the chip.

In summary, persons in the technical field eager for a novel etching method of fabricating a textured solar cell, in which one surface is textured and etched, and the chip is not easily damaged during the etching process or has an additional loss of thickness.

### SUMMARY

The present disclosure provides an etching composition for etching a semiconductor wafer, comprising: based on the total weight of the etching composition (A) 0.5-50 wt % of base; (B) 10-80 wt % of alcohol; (C) 0.01-15 wt % of additive, the additive comprising at least one selected from a group consisting of boron oxide, boric acid, potassium boric acid, sodium tetraborate, aluminum chloride, aluminum hydroxide, phosphoric acid, silicon phosphoric acid, boron phosphate, aluminum phosphate, sulfuric acid, formic acid, acetic acid, citric acid, nitric acid and a combination thereof; and (D) water, wherein the etching composition reacts on the semiconductor wafer at an etching temperature to form a foam that etches the semiconductor wafer and includes a solid, a liquid and a gas.

In an embodiment, when the etching composition is applied to the entire surface or a partial surface of the semiconductor wafer at 60° C.-200° C., the etching composition reacts on the semiconductor wafer to form a foam that etches the semiconductor wafer and includes a solid, a liquid and a gas. The additive forms an oxide mask on the surface of the semiconductor wafer. In another embodiment, the etching composition is applied to the entire surface or a partial surface of the semiconductor wafer at 60° C.-200° C., and the etching composition reacts on the semiconductor wafer to form a foam that includes a solid, a liquid and a gas and etches the semiconductor wafer. At the same time, the additive forms an oxide mask on the surface of the semiconductor wafer.

A method for etching a semiconductor wafer is further provided, including: applying a first etching composition to a first surface of a semiconductor wafer; and etching the semiconductor wafer at an etching temperature, wherein the first etching composition comprises: based on the total weight of the first etching composition, (A) 0.5-50 wt % of base; (B) 10-80 wt % of alcohol; (C) 0.01-15 wt % of additive, the additive includes at least one selected from a group consisting of boron oxide, boric acid, potassium boric acid, sodium tetraborate, aluminum chloride, aluminum hydroxide, phosphoric acid, silicon phosphoric acid, boron phosphate, aluminum phosphate, sulfuric acid, formic acid, acetic acid, citric acid, nitric acid and a combination thereof; and (D) water. In an embodiment, the additive forms an oxide mask on the surface of the semiconductor wafer at the etching temperature at the same time.

Through the use of the etching composition and the method, an excellent texture structure is provided on the surface of the semiconductor wafer. The etching composition and the method can also etch a single surface of the semiconductor wafer, and there is no need to cover a protection mask on the other surface of the semiconductor wafer.

### BRIEF DESCRIPTION OF DRAWINGS

The disclosure can be more fully understood by reading the following detailed description of the embodiments, with reference made to the accompanying drawings, wherein:

FIG. 1 is a flow chart of forming a texture surface of an embodiment according to the present disclosure;

FIG. 2 is a pattern of a single surface of a substrate that is self-foaming etched;

FIG. 3 depicts oxide separated from the single surface of the substrate;

FIG. 4 depicts a surface of a silicon chip etched by an etching composition of an embodiment according to the present disclosure;

FIG. 5 depicts a surface of a silicon chip etched by an etching composition of a comparative example according to the present disclosure;

FIG. 6 depicts a surface of a silicon chip etched by an etching composition of another comparative example according to the present disclosure;

FIG. 7 shows a relation between wavelength segments and the reflectivity of a foamed and etched silicon chip in an embodiment and in a comparative example; and

FIG. 8 shows a relation between wavelength segments and the reflectivity of a foamed and etched silicon chip in an embodiment and a batch-typed immersed and etched silicon chip in a comparative example.

### DETAILED DESCRIPTION

In the following detailed description, for purposes of explanation, numerous specific details are set forth in order to provide a through understanding of the disclosed embodiments. It will be apparent, however, that one or more embodiments may be practiced without these specific details. In other instances, well-known structures and devices are schematically shown in order to simplify the drawing.

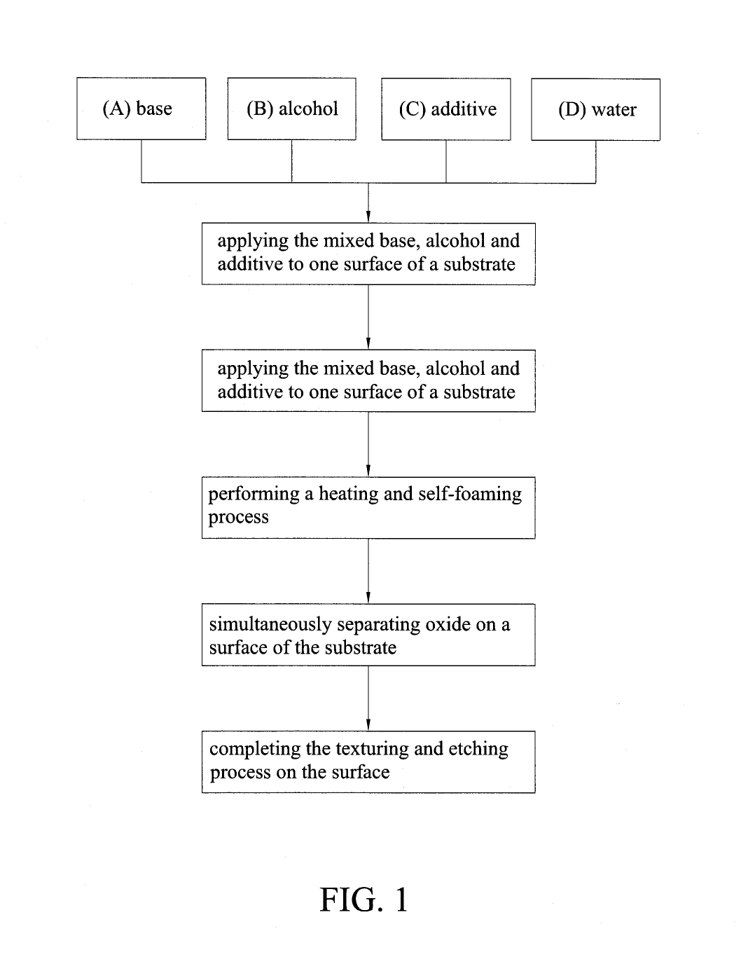

FIG. 1 is a flow chart of forming a texture surface of an embodiment according to the present disclosure. The method comprises: providing (A) base, (B) alcohol, and (C) additive; oscillating and mixing the base, the alcohol and the additive by supersonic waves; applying the mixed base, alcohol and additive to one surface of a substrate; performing a heating and self-foaming process; simultaneously separating oxide on a surface of the substrate; and completing the texturing and etching process on the surface.

As shown in FIG. 1, an etching composition for a semiconductor comprises base, alcohol, and additive, wherein the etching composition reacts on the semiconductor wafer at an etching temperature to form a foam including a solid, a liquid and a gas that etches the semiconductor wafer.

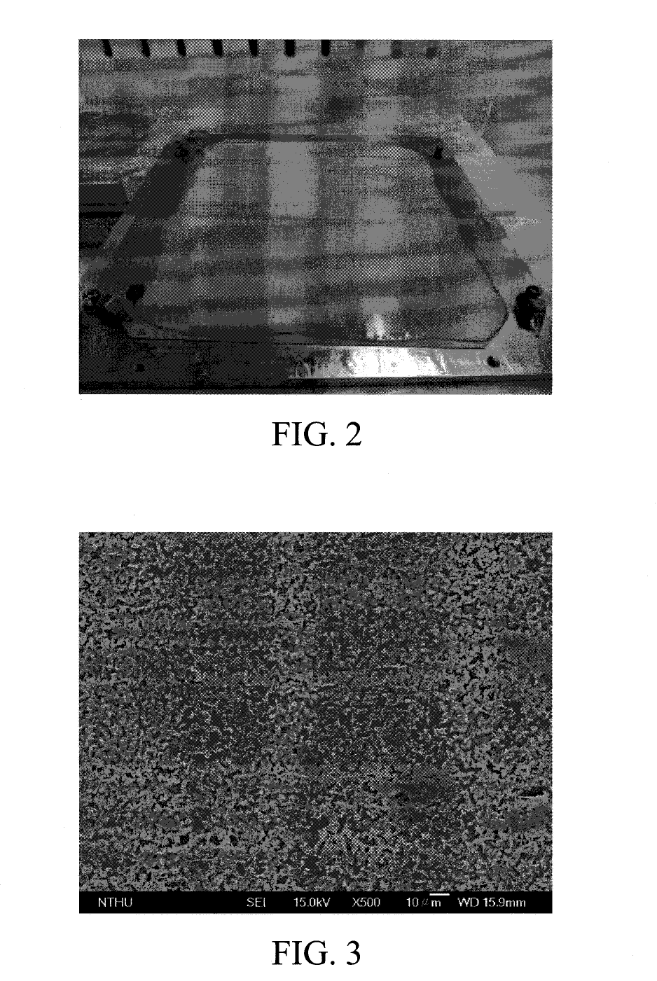

At an appropriate etching temperature, the etching composition forms the foam spontaneously, thereby forming on a surface of the semiconductor wafer a colloidal foam in which solid, liquid and gas co-exist in equilibrium, as shown in FIG. 2. The liquid of the etching composition can be maintained in the colloidal foam and prevented from flowing to a non-etching surface. In other words, the etching composition is easily controlled. Therefore, through the use of the etching composition according to the present disclosure the etching can be performed. According, it is not to immerse the semiconductor wafer and the step of forming a protection cover on the non-etching surface is omitted. In an embodiment, the etching temperature ranges from 60° C. to 200° C. In another embodiment, the etching temperature ranges from 80° C. to 150° C.

In the etching process, the additive reacts on the semiconductor wafer to form oxide that covers the surface of the semiconductor wafer randomly, as shown in FIG. 3. Through the use of the etching composition, a texture structure can be formed on a surface of a semiconductor to reduce the reflectivity. In an embodiment, the etching composition according to the present disclosure is used to form a silicon chip having a texture structure on a surface thereof, so as to fabricate a silicon chip solar cell having high conversion efficiency.

In an embodiment, the base comprises sodium hydroxide, potassium hydroxide, potassium carbonate or a combination thereof; the alcohol comprises ethylene glycol, diethylene glycol, glycerol, triethylene glycol or a combination thereof; and the additive comprises at least one selected from a group consisting of boron oxide, boric acid, potassium boric acid, sodium tetraborate, aluminum chloride, aluminum hydroxide, phosphoric acid, silicon phosphoric acid, boron phosphate, aluminum phosphate, sulfuric acid, formic acid, acetic acid, citric acid, nitric acid and a combination thereof.

In an embodiment, the etching composition comprises, based on the total weight of the etching composition, 0.5-50 wt % of base, 10-80 wt % of alcohol, and 0.01-15 wt % of additive.

In an embodiment, the semiconductor wafer is made of silicon, germanium or a combination thereof. In an embodiment, if the semiconductor wafer is made of silicon, the silicon is monocrystalline silicon, polycrystalline silicon or a combination thereof.

In an embodiment, the etching composition comprises an additional component such as water.

The method of etching a semiconductor wafer comprises: applying a first etching composition to a first surface of a semiconductor wafer; and etching the semiconductor wafer at an etching temperature, wherein the first etching composition comprises: based on the total weight of the first etching composition, 0.5-50 wt % of base, 10-80 wt % of alcohol, 0.01-15 wt % of additive, and water, and the additive comprises at least one selected from a group consisting of boron oxide, boric acid, potassium boric acid, sodium tetraborate, aluminum chloride, aluminum hydroxide, phosphoric acid, silicon phosphoric acid, boron phosphate, aluminum phosphate, sulfuric acid, formic acid, acetic acid, citric acid, nitric acid and a combination thereof. In an embodiment, the etching temperature ranges between 60° C. and 200° C. In another embodiment, the etching temperature ranges between 80° C. and 150° C.

In the embodiment, the method further comprises: applying a second etching composition to a second surface of the semiconductor wafer; and etching the semiconductor wafer at 60° C. to 200° C., wherein the second etching composition comprises: 0.5-50 wt % of base; and 10-80 wt % of alcohol, based on the total weight of the second etching composition.

In an embodiment, the additive of the first etching composition comprises at least one selected from a group consisting of boron oxide, boric acid, potassium boric acid, sodium tetraborate, aluminum chloride, aluminum hydroxide, phosphoric acid, silicon phosphoric acid, boron phosphate, aluminum phosphate, sulfuric acid, formic acid, acetic acid, citric acid, nitric acid and a combination thereof.

In an embodiment, the base of the first and second etching compositions comprises sodium hydroxide, potassium hydroxide, potassium carbonate or a combination thereof, and the alcohol of the first and second etching compositions comprises ethylene glycol, diethylene glycol, glycerol, triethylene glycol or a combination thereof.

In an embodiment, the first etching composition comprises 0.5-50 wt % of base, 10-80 wt % of alcohol, and 0.01-15 wt % of additive, based on the total weight of the first etching composition.

In an embodiment, the second etching composition comprises 0.5-50 wt % of base and 10-80 wt % of alcohol, based on the total weight of the second etching composition. In an embodiment, the semiconductor wafer is heated to the etching temperature before the application of the etching composition. In another embodiment, the semiconductor wafer is heated to the etching temperature after the application of the etching composition.

In an embodiment, the second etching composition comprises an additional component such as water.

The application of the first and second etching compositions can be performed by spray coating, spin coating, screen printing or a scraper.

The features and efficacy of the present disclosure are described according the specific embodiments, which, however, are not used to limit the scope of the present disclosure.

### Embodiments

### The Preparation of the Etching Composition

Table 1 lists the components of the etching composition and their wt % in embodiments 1-8 and comparative examples 1-5. In embodiments 1-8, the etching composition prepared mainly comprises: 0.5-50 wt % of base; 10-80 wt % of alcohol; and 0.01-15 wt % of additive. In comparative examples 1-4, the etching composition prepared mainly comprises: 0.5-50 wt % of base; and 10-80 wt % of alcohol. In comparative example 5, the etching composition prepared mainly comprises: 1.5 wt % of potassium hydroxide and 3 wt % of isopropyl alcohol.

TABLE 1

| | the components of the etching composition and their wt % | | | | | | |
|---|---|---|---|---|---|---|---|
| | | | | Base | alcohol | Additive | water |
| | base | alcohol | additive | (wt %) | (wt %) | (wt %) | (wt %) |
| embodi- | potassium | ethylene | Boric acid | 10 | 80 | 5 | 5 |
| ment 1 | hydroxide | glycol | | | | | |
| embodi- | potassium | diethylene | Boric acid | 20 | 70 | 7.5 | 2.5 |
| ment 2 | hydroxide | glycol | | | | | |
| embodi- | potassium | glycerol | Boric acid | 30 | 50 | 12 | 8 |
| ment 3 | hydroxide | | | | | | |
| embodi- | potassium | triethylene | Boric acid | 20 | 60 | 10 | 10 |
| ment 4 | hydroxide | glycol | | | | | |
| embodi- | potassium | ethylene | Boric acid | 15 | 80 | 1 | 4 |
| ment 5 | carbonate | glycol | | | | | |
| embodi- | potassium | diethylene | Boric acid | 20 | 70 | 0.75 | 9.25 |
| ment 6 | carbonate | glycol | | | | | |
| embodi- | potassium | glycerol | Boric acid | 25 | 60 | 0.75 | 14.25 |
| ment 7 | carbonate | | | | | | |
| embodi- | potassium | triethylene | Boric acid | 20 | 70 | 0.5 | 9.5 |
| ment 8 | carbonate | glycol | | | | | |
| Com. | potassium | ethylene | nil | 15 | 80 | — | 5 |
| Ex. 1 | carbonate | glycol | | | | | |
| Com. | potassium | diethylene | nil | 20 | 70 | — | 10 |
| Ex. 2 | carbonate | glycol | | | | | |
| Com. | potassium | glycerol | nil | 25 | 60 | — | 15 |
| Ex. 3 | carbonate | | | | | | |
| Com. | potassium | triethylene | nil | 20 | 70 | — | 10 |
| Ex. 4 | carbonate | glycol | | | | | |
| Com. | potassium | isopropyl | nil | 1.5 | 3 | — | 95.5 |
| Ex. 5 | hydroxide | alcohol | | | | | |

### Spontaneous Foaming and Etching

Twelve silicon chips are provided. The etching compositions in embodiments 1-8 and comparative examples 1-4 were applied to the surface of the twelve silicon chips by screen printing. Then, the silicon chips were heated to 120° C. for eight minutes. Last, the etching composition was washed out. Therefore, the silicon chip has a textured surface.

### Batch-Typed Immerse Etching

A silicon chip having a protection cover formed on a rear surface thereof was provided. The silicon chip was immersed in the etching composition in comparative example 5 and was heated to 80° C. The silicon chip is was etched for 30 minutes. Then, the etching composition was washed out. Last, the protection cover was removed. Therefore, the silicon chip has a textured surface.

### Observing and Evaluating the Textured Surface

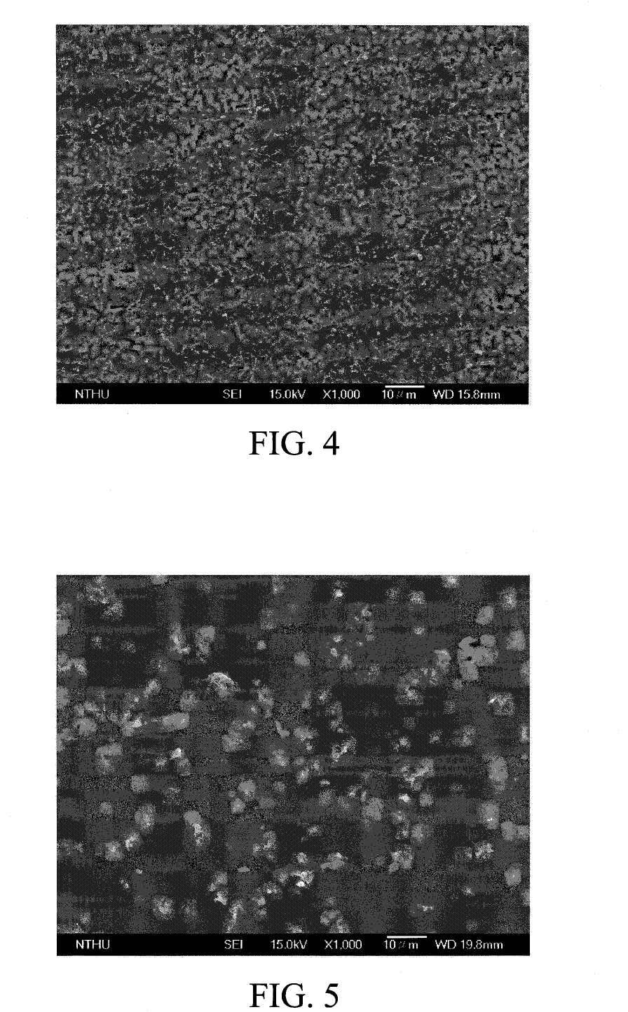

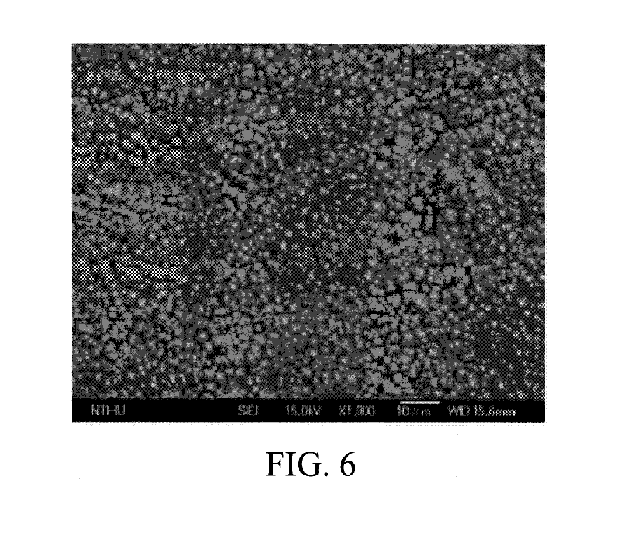

The textured surface of the silicon chip was observed by a scanning electron microscopy. As shown in FIG. 4, a plurality of dense pyramid structures, i.e., an excellent texture structure, are formed on the surface of the silicon chip. FIG. 5 shows the surface of the silicon chip etched by the etching composition in comparative example 3. It can be seen from FIG. 5 that the texture structure is not obvious. FIG. 6 shows the surface of the silicon chip etched by the etching composition of comparative example 5. It can be seen from FIG. 6 that the pyramid structure is dense, but it takes longer time to etch in comparative example 5. Besides, since the etching composition in comparative example 5 contains isopropyl alcohol that has a low boiling point, the etching composition consumes rapidly and needs to be refilled all the time, which increases the cost of the etching material and manufacturing equipment. Moreover, the batch-typed immerse etching makes the chip have rough structures on both surfaces thereof, which adversely affects the fabrication of a high-efficiency silicon chip solar cell.

As shown in Table 2, the standards for evaluating the textured process effect are as follows:

⊚: excellent

◯: good

Δ: acceptable

X: poor

TABLE 2

| | | Textured |
|---|---|---|
| Etching composition | Etching manner | process effect |
| Embodiment 1 | spontaneous foaming and etching | Δ |
| Embodiment 2 | spontaneous foaming and etching | ◯ |
| Embodiment 3 | spontaneous foaming and etching | ⊚ |
| Embodiment 4 | spontaneous foaming and etching | ⊚ |
| Embodiment 5 | spontaneous foaming and etching | ◯ |
| Embodiment 6 | spontaneous foaming and etching | ◯ |
| Embodiment 7 | spontaneous foaming and etching | ⊚ |
| Embodiment 8 | spontaneous foaming and etching | ⊚ |
| Com. Ex. 1 | spontaneous foaming and etching | X |
| Com. Ex. 2 | spontaneous foaming and etching | X |
| Com. Ex. 3 | spontaneous foaming and etching | X |
| Com. Ex. 4 | spontaneous foaming and etching | X |
| Com. Ex. 5 | Batch-typed immerse etching | ⊚ |

### Measurement of Reflectivity

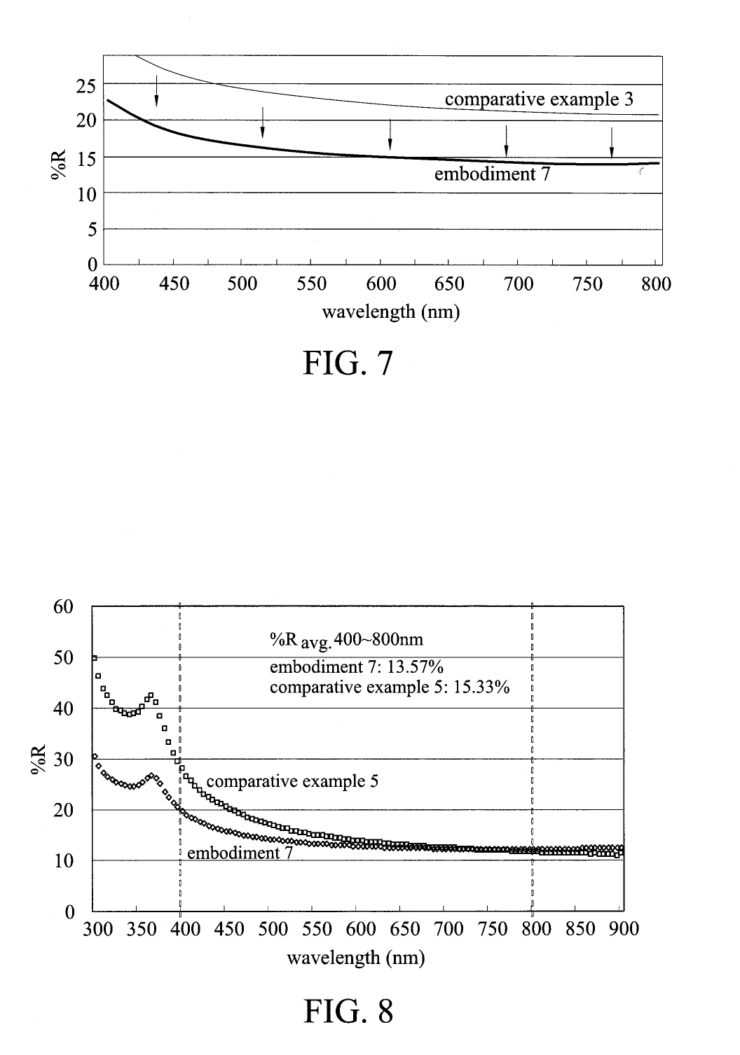

The reflectivity of the etched surface of the silicon chip is measured with JASCO V670 Research LW-Visible Spectrophotometer. FIG. 7 shows a relation between wavelength segments and the reflectivity of the foamed and etched silicon chip in embodiment 7 and comparative example 3. As shown in FIG. 7, the reflectivity of the silicon chip, after etched by the etching composition containing boric acid in embodiment, is low. In other words, the silicon chip has excellent anti-reflectivity. FIG. 8 shows a relation between wavelength segments and the reflectivity of the silicon chip in embodiment 7 and comparative example 5. As shown in FIG. 8, the reflectivity of the silicon chip, after etched by the etching composition containing boric acid in embodiment 7, is low. In other words, the silicon chip has excellent anti-reflectivity.

It will be apparent to those skilled in the art that various modifications and variations can be made to the disclosed embodiments. It is intended that the specification and examples be considered as exemplary only, with a true scope of the disclosure being indicated by the following claims and their equivalents.

1. An etching composition for etching a semiconductor wafer, comprising:
(A) 0.5-50 wt % of base, based on the total weight of the etching composition;
(B) 10-80 wt % alcohol, based on the total weight of the etching composition;
(C) 0.01-15 wt % additive, based on the total weight of the etching composition,
wherein the additive comprises at least one selected from the group consisting of boron oxide, boric acid, potassium borate, sodium tetraborate, aluminum chloride, silicon phosphate, boron phosphate, aluminum phosphate, sulfuric acid, formic acid, acetic acid, citric acid, nitric acid and a combination thereof; and
(D) water,
wherein the etching composition reacts on the semiconductor wafer at an etching temperature ranging between 120° C. and 200° C. to form a foam that etches the semiconductor wafer and includes a solid, a liquid and a gas.

2. The etching composition for etching a semiconductor wafer of claim 1, wherein the semiconductor wafer is fabricated from silicon, germanium or a combination thereof.

3. The etching composition for etching a semiconductor wafer of claim 1, wherein the semiconductor wafer is fabricated from monocrystalline silicon, polycrystalline silicon or a combination thereof.

4. The etching composition for etching a semiconductor wafer of claim 1, wherein the base comprises sodium hydroxide, potassium hydroxide, potassium carbonate or a combination thereof.

5. The etching composition for etching a semiconductor wafer of claim 1, wherein the alcohol comprises ethylene glycol, diethylene glycol, glycerol, triethylene glycol or a combination thereof.

6. (canceled)

7. A method for etching a semiconductor wafer, comprising:
applying a first etching composition to a first surface of a semiconductor wafer; and
etching the semiconductor wafer at an etching temperature,
wherein the first etching composition comprises:
(A) 0.5-50 wt % base, based on the total weight of the first etching composition;
(B) 10-80 wt % alcohol, based on the total weight of the first etching composition;
(C) 0.01-15 wt % additive, based on the total weight of the first etching composition, wherein the additive includes at least one selected from a group consisting of boron oxide, boric acid, potassium boric acid, sodium tetraborate, aluminum chloride, aluminum hydroxide, phosphoric acid, silicon phosphoric acid, boron phosphate, aluminum phosphate, sulfuric acid, formic acid, acetic acid, citric acid, nitric acid and a combination thereof; and
(D) water.

8. The method of claim 7, wherein the semiconductor wafer is heated to the etching temperature before the first etching composition is applied to the first surface of the semiconductor wafer.

9. The method of claim 7, wherein the semiconductor wafer is heated to the etching temperature after the first etching composition is applied to the first surface of the semiconductor wafer.

10. The method of claim 7, wherein the first etching composition is heated to the etching temperature after the first etching composition is applied to the first surface of the semiconductor wafer.

11. The method of claim 7, wherein the etching temperature ranges from 60° C. to 200° C.

12. The method of claim 7, wherein the etching temperature ranges from 80° C. to 150° C.

13. The method of claim 7, wherein the step of applying the first etching composition is performed by spray coating, spin coating, screen printing or a scraper.

14. The method of claim 7, wherein the semiconductor wafer is fabricated from silicon, germanium and a combination thereof.

15. The method of claim 7, wherein the semiconductor wafer is fabricated from monocrystalline silicon, polycrystalline silicon or a combination thereof.

16. The method of claim 7, wherein the base comprises sodium hydroxide, potassium hydroxide, potassium carbonate or a combination thereof.

17. The method of claim 7, wherein the alcohol comprises ethylene glycol, diethylene glycol, glycerol, triethylene glycol or a combination thereof.

18. The method of claim 7, wherein the additive forms an oxide mask on the first surface of the semiconductor wafer at the etching temperature.

19. The method of claim 7, further comprising:
applying a second etching composition to a second surface of the semiconductor wafer; and
etching the semiconductor wafer at 60-200° C.,
wherein the second etching composition comprising:
(A) 0.5-50 wt % base, based on the total weight of the second etching composition; and
(B) 10-80 wt % alcohol, based on the total weight of the second etching composition.

20. The method of claim 19, wherein the base of the second etching composition comprises sodium hydroxide, potassium hydroxide, potassium carbonate or a combination thereof.

21. The method of claim 19, wherein the alcohol of the second etching composition comprises ethylene glycol, diethylene glycol, glycerol, triethylene glycol or a combination thereof.
